(19) United States
(12) Patent Application Publication
(10) Pub. No.: US 2012/0299114 A1
(43) Pub. Date: Nov. 29, 2012

(54) SEMICONDUCTOR DEVICE AND METHOD OF MANUFACTURING THE SAME

(75) Inventor: Seiji OTAKE, Kumagaya-shi (JP)

(73) Assignee: Semiconductor Components Industrires, LLC, Phoenix, AZ (US)

(21) Appl. No.: 13/478,954

(22) Filed: May 23, 2012

(30) Foreign Application Priority Data
May 24, 2011 (JP) 2011-115618

(51) Int. Cl. H01L 27/06; H01L 21/8249

(52) U.S. Cl. 257/370; 438/207; 257/E27.015; 257/E21.696

(57) ABSTRACT

The invention is directed to a semiconductor device which is manufactured by a BiCMOS process in which a process of manufacturing a V-NPN transistor is rationalized. Furthermore, the hFE of the transistor is adjusted to a large value. An N type base width control layer is formed being in contact with a bottom portion of a P type base region under an N+ type emitter region. The N type base width control layer shallows a portion of the P type base region under the N+ type emitter region partially. The P type base region is formed by using a process of forming a P type well region, and the N type base width control layer is formed by using a process of forming an N type well region, thereby achieving the process rationalization.

### CROSS-REFERENCE OF THE INVENTION

This application claims priority from Japanese Patent Application No. 2011-115618, filed May 24, 2011, the content of which is incorporated herein by reference in its entirety.

### BACKGROUND OF THE INVENTION

1. Field of the Invention

The invention relates to a semiconductor device manufactured by a BiCMOS process and a method of manufacturing the same.

2. Description of the Related Art

A semiconductor device having a P channel type MOS transistor (hereafter, referred to as a PMOS transistor), an N channel type MOS transistor (hereafter, referred to as an NMOS transistor) and a vertical NPN bipolar transistor (hereafter, referred to as a V-NPN transistor) formed on one semiconductor substrate by a BiCMOS process has been known conventionally. This type of semiconductor device is described in Japanese Patent Application publication No. 2003-197792.

In this case, a dedicated process for forming the P type base region of the V-NPN transistor is provided so as to adjust the characteristics of the V-NPN transistor, in particular, the hFE (direct current amplification factor) to a desired value. Furthermore, for process rationalization, the P type base region is formed by using the process of forming the P type well region instead of by a dedicated process.

However, when the P type base region is formed by using a process of forming the P type well region, the impurity profile of the base region becomes the same as the impurity profile of the P type well region and thus the desired characteristics of the V-NPN transistor are not obtained. In particular, the hFE is lower than a desired value.

### SUMMARY OF THE INVENTION

The invention provides a semiconductor device including: a semiconductor layer of a first general conductivity type; a first MOS transistor of a first general conductivity channel type formed in the semiconductor layer; a second MOS transistor of a second general conductivity channel type formed in the semiconductor layer; a vertical bipolar transistor formed in the semiconductor layer; and an isolation layer of the first general conductivity type electrically isolating the vertical bipolar transistor from the first and second MOS transistors, wherein the vertical bipolar transistor comprises a base region of the second general conductivity type formed in a surface of the semiconductor layer, an emitter region of the first general conductivity type formed in a surface of the base region, and a base width control layer of the first general conductivity type extending from a bottom of the base region under the emitter region to upper area and lower area.

The invention also provides a method of manufacturing a semiconductor device, including: forming a first well region of a second general conductivity type in a surface portion of a semiconductor layer of a first general conductivity type; forming a first MOS transistor of a first general conductivity channel type in the first well region; forming a second well region of the first general conductivity type in a surface portion of the semiconductor layer; forming a second MOS transistor of a second general conductivity channel type in the second well region; forming a vertical bipolar transistor in the semiconductor layer; and forming an isolation layer of the first general conductivity type electrically isolating a region of the semiconductor layer in which the vertical bipolar transistor is formed from the first and second MOS transistors, the step of forming the vertical bipolar transistor, including: forming a base region of the second general conductivity type in a surface portion of the semiconductor layer isolated by the isolation layer; forming an emitter region of the first general conductivity type in a surface portion of the base region; and forming a base width control layer of the first general conductivity type being in contact with a bottom portion of the base region under the emitter region so as to shallow the base region under the emitter region, wherein the base region is formed by using the step of forming the first well region and the base width control layer is formed by using the step of forming the second well region.

### BRIEF DESCRIPTION OF THE DRAWINGS

FIG. 1 is a cross-sectional view of a semiconductor device of a first embodiment of the invention.

FIG. 2 is a plan view of the V-NPN transistor of the semiconductor device of the first embodiment of the invention.

FIGS. 3A and 3B are graphs showing the impurity profiles of the P type well region, the N+ type well region, the P type base region and the N type base width control layer of the first embodiment of the invention.

FIG. 4 is a cross-sectional view of a semiconductor device of a second embodiment of the invention.

FIG. 5 is a cross-sectional view of a semiconductor device of a third embodiment of the invention.

FIG. 6 is a cross-sectional view of a semiconductor device of a fourth embodiment of the invention.

FIG. 7 is a cross-sectional view of a semiconductor device of a comparison example.

### DETAILED DESCRIPTION OF THE INVENTION

### First Embodiment

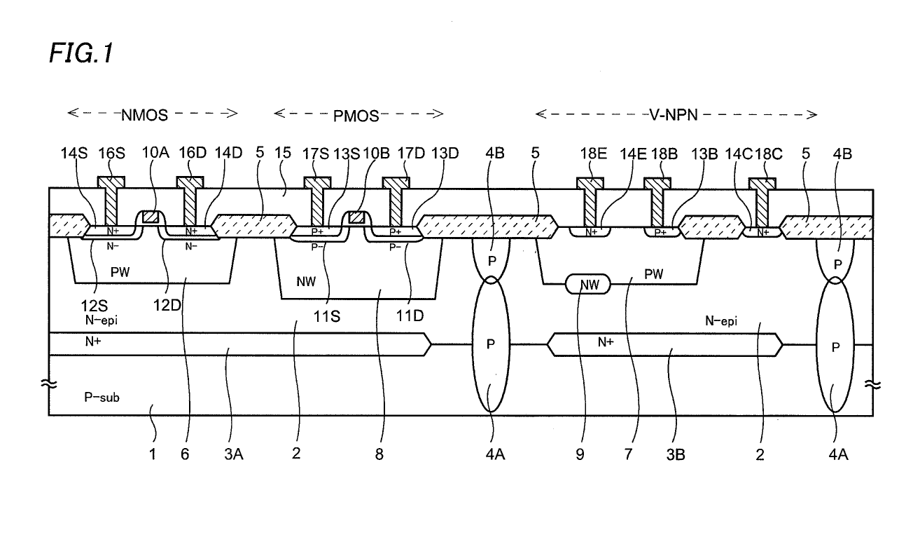

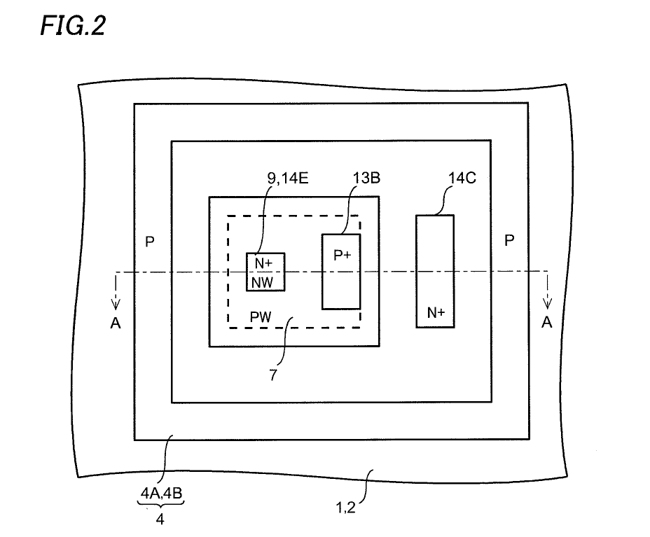

FIG. 1 is a cross-sectional view of a semiconductor device of a first embodiment of the invention. FIG. 2 is a plan view of the V-NPN transistor of the semiconductor device. A cross-sectional view of FIG. 2 along line A-A corresponds to the cross-sectional view of the V-NPN transistor in FIG. 1. In FIG. 2, a P type isolation layer 4, a P type base region 7, an N+ type emitter region 14E, a P+ type base electrode drawing layer 13B, and an N+ type collector electrode drawing layer 14C in FIG. 1 is shown.

An N− type epitaxial semiconductor layer 2 is formed on a semiconductor substrate 1 made of P type single crystal. The semiconductor substrate 1 and the N− type epitaxial semiconductor layer 2 form a PN junction. In a region where an NMOS transistor and a PMOS transistor are formed, an N+ type buried layer 3A is formed in a PN junction portion between the semiconductor substrate 1 and the N− type epitaxial semiconductor layer 2 so as to decrease the resistance of the N− type epitaxial semiconductor layer 2 (the substrate of the PMOS transistor).

In a region where the V-NPN transistor is formed, an N+ type buried layer 3B is formed in a PN junction portion between the semiconductor substrate 1 and the N− type epitaxial semiconductor layer 2 so as to decrease the resistance of the N− type epitaxial semiconductor layer 2 (the collector region of the V-NPN transistor).

A first portion of the N− type epitaxial semiconductor layer 2 where the V-NPN transistor is formed is electrically isolated from a second portion of the N− type epitaxial semiconductor layer 2 where the NMOS transistor and the PMOS transistor are formed by a P type isolation layer 4 including a P type lower isolation layer 4A and a P type upper isolation layer 4B. In detail, the P type lower isolation layer 4A is formed by upward and downward diffusion from the PN junction portion between the semiconductor substrate 1 and the N− type epitaxial semiconductor layer 2, and the P type upper isolation layer 4B is formed by downward diffusion from the front surface of the epitaxial semiconductor layer 2. The upper end portion of the P type lower isolation layer 4A and the lower end portion of the P type upper isolation layer 4B are overlapped. This P type isolation layer 4 completely surrounds the first portion of the N− type epitaxial semiconductor layer 2 where the V-NPN transistor is formed, as shown in FIG. 2.

A field insulation film such as, for example, a LOCOS (Local Oxidation of Silicon) film 5 is formed on the front surface of the N− type epitaxial semiconductor layer 2. A surface portion of the epitaxial semiconductor layer 2 on which the LOCOS film 5 is not formed is the active region of the NMOS transistor, the PMOS transistor and the V-NPN transistor.

In the NMOS transistor, a P type well region 6 is formed in a surface portion of the N− type epitaxial semiconductor layer 2. The P type upper isolation layer 4B described above may be formed by using the process of forming the P type well region 6 (the ion implantation and diffusion of P type impurities such as boron) for process rationalization.

A gate electrode 10A is formed on the surface of the P type well region 6 through a gate insulation film. A sidewall spacer insulation film is formed on the sidewall of the gate electrode 10A. The source layer and drain layer of the NMOS transistor are formed in a surface portion of the P type well region 6 on either side of the gate electrode 10A respectively. The source layer includes an N+ type source layer 14S and an N− type source layer 12S which is deeper and has a lower concentration than the N+ type source layer 14S. The drain layer includes an N+ type drain layer 14D and an N− type drain layer 12D which is deeper and has a lower concentration than the N+ type drain layer 14D. The N+ type source layer 14S and the N+ type drain layer 14D are formed by self-alignment with the side end of the sidewall spacer insulation film. The N− type source layer 12S and the N− type drain layer 12D are formed by self-alignment with the side end of the gate electrode 10A.

The PMOS transistor is formed in an N type well region 8 formed in a surface portion of the N− type epitaxial semiconductor layer 2, abutting the NMOS transistor between which the LOCOS film 5 is disposed. A gate electrode 10B is formed on the surface of the N type well region 8 through a gate insulation film.

A sidewall spacer insulation film is formed on the sidewall of the gate electrode 10B of the PMOS transistor. The source layer and drain layer of the PMOS transistor are formed in a surface portion of the N type well region 8 on either side of the gate electrode 10B respectively. The source layer includes a P+ type source layer 13S and a P− type source layer 11S which is deeper and has a lower concentration than the P+ type source layer 13S. The drain layer includes a P+ type drain layer 13D and a P− type drain layer 11D which is deeper and has a lower concentration than the P+ type drain layer 13D. The P+ type source layer 13S and the P+ type drain layer 13D are formed by self-alignment with the side end of the sidewall spacer insulation film. The P− type source layer 11S and the P− type drain layer 11D are formed by self-alignment with the side end of the gate electrode 10B.

The V-NPN transistor is formed in the portion of the N− type epitaxial semiconductor layer 2 isolated by the P type isolation layer 4. In detail, a P type base region 7 is formed in a surface portion of the N− type epitaxial semiconductor layer 2. An N+ type emitter region 14E is formed in a surface portion of the P type base region 7. Furthermore, a P+ type base electrode drawing layer 13B is formed in a surface portion of the P type base region 7 adjacent to the N+ type emitter region 14E. Furthermore, an N+ type collector electrode drawing layer 14C is formed in a surface portion of the N− type epitaxial semiconductor layer 2 isolated by the P type isolation layer 4 adjacent to the P type base region 7. The N− type epitaxial semiconductor layer 2 isolated by the P type isolation layer 4 is an N− type collector region.

An N type base width control layer 9 is formed being in contact with a bottom portion of the P type base region 7 under the N+ type emitter region 14E. The N type base width control layer 9 shallows a portion of the P type base region 7 under the N+ type emitter region 14E. By this, the base width under the N+ type emitter region 14E (the vertical width of the P type base region 7 between the N+ type emitter region 14E and the N type base width control layer 9) is decreased, thereby increasing the hFE (direct current amplification factor) of the V-NPN transistor.

The P type base region 7 is formed by using the process of forming the P type well region 6 (the ion implantation and diffusion of P type impurities such as boron), and the N type base width control layer 9 is formed by using the process of forming the N type well region 8 (the ion implantation and diffusion of N type impurities such as phosphorus), thereby achieving process rationalization.

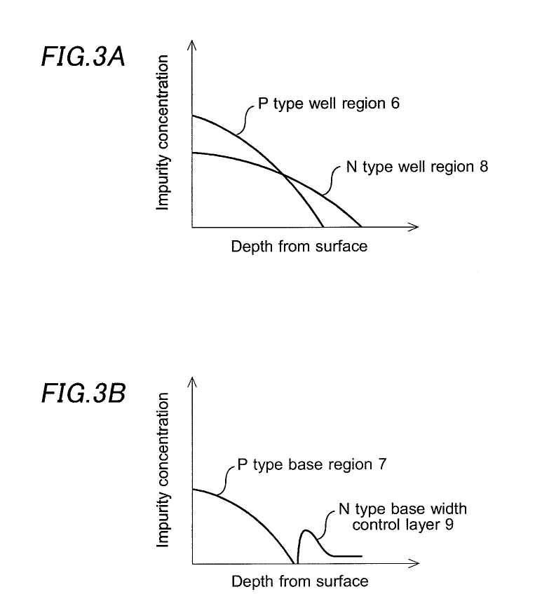

Details will be described in this point. FIG. 3A is a graph showing the impurity profiles of the P type well region 6 and the N type well region 8, and FIG. 3B is a graph showing the impurity profiles of the P type base region 7 and the N type base width control layer 9. As shown in FIG. 3A, the impurity concentration of the P type well region 6 in the surface is set higher than the impurity concentration of the N type well region 8 in the surface, and the P type well region 6 is diffused shallower than the N type well region 8.

P type impurities are implanted into the whole region where the P type base region 7 is to be formed under the same condition as for the P type well region 6 (the condition of the ion implantation and thermal diffusion), and N type impurities are implanted into the region where the N+ type emitter region 14E is to be formed over the P type impurities under the same condition as for the N type well region 8 (the condition of the ion implantation and thermal diffusion). As a result, as shown in FIG. 3B, the P type impurities are compensated by the N type impurities in the region for the N+ type emitter region 14E, the P type base region 7 under this region becomes shallow, and the N type base width control layer 9 is formed being in contact with a bottom portion of the P type base region 7. The vertical width of the P type base region 7 between the N+ type emitter region 14E and the N type base width control layer 9 is the base width.

In this case, it may be possible that the N type base width control layer 9 is formed being in contact with the whole bottom portion of the P type base region 7 so as to shallow the whole P type base region 7 by implanting P type impurities and N type impurities into the whole region where the P type base region 7 is to be formed under the same condition as for the P type well region 6 and the N type well region 8. However, this causes a problem that the resistance of the P type base region 7 increases to decrease the switching speed of the V-NPN transistor. Therefore, in order to increase the hFE without decreasing the switching speed of the V-NPN transistor, it is necessary to shallow a portion of the P type base region 7 under the N+ type emitter region 14E.

As an example, the depth of the P type well region 6 (=the depth of the P type base region 7 in the region where the N type base width control layer 9 is not formed) is 1.6 μm, and the depth of the N+ type emitter region 14E is 0.2 μm. Thus, the base width of the region where the N type base width control layer 9 is not formed is 1.4 μm, while the base width of the region under the N+ type emitter region 14E where the N type base width control layer 9 is formed is 1.0 μm and smaller. The hFE is about 30 when the N type base width control layer 9 is not formed, while the hFE is about 170 when the N type base width control layer 9 is formed.

Furthermore, for process rationalization, the N+ type emitter region 14E and the N+ type collector electrode drawing layer 14C are formed by using the process of forming the N+ type source layer 14S and the N+ type drain layer 14D of the NMOS transistor (the ion implantation of N type impurities), and further the P+ type base electrode drawing layer 13B is formed by using the process of forming the P+ type source layer 13S and P+ type drain layer 13D of the PMOS transistor (the ion implantation of P type impurities).

The surface of the N− type epitaxial semiconductor layer 2 in which the NMOS transistor, the PMOS transistor and the V-NPN transistor are formed is covered by an interlayer insulation film 15 made of BPSG or the like formed by a CVD method. Furthermore, a source electrode 16S and a drain electrode 16D are formed being electrically connected to the N+ type source layer 14S and N+ type drain layer 14D of the NMOS transistor respectively through contact holes formed in the interlayer insulation film 15. Similarly, a source electrode 17S and a drain electrode 17D are formed being electrically connected to the P+ type source layer 13S and P+ type drain layer 13D of the PMOS transistor respectively. Similarly, an emitter electrode 18E, a base electrode 18B and a collector electrode 18C are formed being electrically connected to the N+ type emitter region 14E, the P+ type base electrode drawing layer 13B and the N+ type collector electrode drawing layer 14C of the V-NPN transistor respectively.

Hereafter, a method of manufacturing the semiconductor device of the first embodiment will be described referring to FIGS. 1 to 3B. First, after a first photolithography process, N type impurities such as phosphorus or the like are selectively ion-implanted into a surface portion of the semiconductor substrate 1 made of P type single crystal silicon in the region where the N+ type buried layers 3A and 3B are to be formed. Furthermore, after a second photolithography process, P type impurities such as boron or the like are selectively ion-implanted into a surface portion of the semiconductor substrate 1 in the region where the P type lower isolation layer 4A is to be formed.

Then the N− type epitaxial semiconductor layer 2 is formed on the surface of the semiconductor substrate 1 by epitaxial growth. At this time, the N type impurities and the P type impurities implanted in the surface portion of the semiconductor substrate 1 are diffused, thereby forming the N+ type buried layers 3A and 3B and the P type lower isolation layer 4A.

Then the LOCOS film 5 is formed on the N− type epitaxial semiconductor layer 2 by a selective oxidation method. Then, after a third photolithography process, boron is selectively ion-implanted into the N− type epitaxial semiconductor layer 2 in the regions where the P type well region 6, the P type base region 7 and the P type upper isolation layer 4B are to be formed. The condition of this ion implantation is acceleration energy of 40 to 400 KeV and a dose of 5×10¹² to 2×10¹⁴/cm², for example. Furthermore, after a fourth photolithography process, phosphorus is selectively ion-implanted in the N− type epitaxial semiconductor layer 2 in the regions where the N type well region 8 and the N type base width control layer 9 are to be formed. The condition of this ion implantation is acceleration energy of 80 to 500 KeV and a dose of 1×10¹² to 1×10¹⁴/cm², for example.

Then, the boron and phosphorus implanted in the N− type epitaxial semiconductor layer 2 are thermally diffused under the condition of 800 to 1150° C. and 10 minutes to 2 hours, for example, thereby forming the P type well region 6, the P type base region 7, the P type upper isolation layer 4B, the N type well region 8 and the N type base width control layer 9 simultaneously. It is noted that the order of the ion implantation process for forming the P type well region 6 and so on and the ion implantation process for forming the N type well region 8 and so on may be reversed. Furthermore, the thermal diffusion process may be performed by two steps in order to adjust both the impurity profiles. For example, it is also possible that the first thermal diffusion is performed after the N type well region 8 and so on are formed, then the P type well region 6 and so on are formed, and the second thermal diffusion is performed.

Then the gate insulation film is formed by thermal oxidation, and the gate electrode 10A of the NMOS transistor and the gate electrode 10B of the PMOS transistor are formed on the gate insulation film. Then, after a fifth photolithography process, the N− type source layer 12S and N− type drain layer 12D of the NMOS transistor are formed by ion implantation of phosphorus. The condition of this ion implantation is acceleration energy of 10 to 100 KeV and a dose of 5×10¹² to 5×10¹⁴/cm², for example.

Then, after a sixth photolithography process, the P− type source layer 11S and P− type drain layer 11D of the PMOS transistor are formed by ion implantation of boron. The condition of this ion implantation is acceleration energy of 10 to 100 KeV and a dose of 5×10¹² to 5×10¹⁴/cm², for example. Then thermal diffusion may be performed so as to deepen the N− type source layer 12S, the N− type drain layer 12D, the P− type source layer 11S and the P− type drain layer 11D.

Then the sidewall spacer insulation film is formed on the sidewalls of the gate electrodes 10A and 10B. The sidewall spacer insulation film is formed by depositing an insulation film such as SiO₂ or the like on the whole surface of the N− type epitaxial semiconductor layer 2 by a CVD method and etching back this insulation film.

Then, after a seventh photolithography process, the N+ type source layer 14S and N+ type drain layer 14D of the NMOS transistor and the N+ type emitter region 14E and N+ type collector electrode drawing layer 14C of the V-NPN transistor are formed by ion implantation of arsenic. The condition of this ion implantation is acceleration energy of 10 to 100 KeV and a dose of 5×10¹⁴ to 5×10¹⁶/cm², for example.

Then, after an eighth photolithography process, the P+ type source layer 13S and P+ type drain layer 13D of the PMOS transistor and the P+ type base electrode drawing layer 13B of the V-NPN transistor are formed by ion implantation of BF₂. The condition of this ion implantation is acceleration energy of 5 to 50 KeV and a dose of 2×10¹⁴ to 2×10¹⁶/cm², for example.

Then, the interlayer insulation film 15 made of BPSG or the like is formed by a CVD method on the surface of the N− type epitaxial semiconductor layer 2 where the NMOS transistor, the PMOS transistor and the V-NPN transistor are formed. Then contact holes are formed in the interlayer insulation film 15, and the electrodes such as the source electrode 16S, the drain electrode 16D and so on are formed.

### Second Embodiment

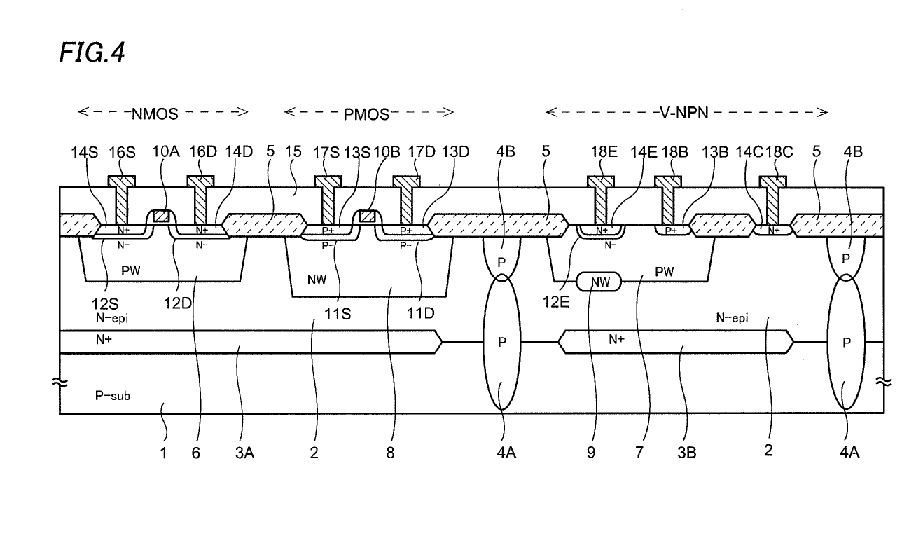

FIG. 4 is a cross-sectional view of a semiconductor device of a second embodiment of the invention. The second embodiment differs from the first embodiment (FIG. 1) in that an N− type emitter region 12E having a concentration lower than the N+ type emitter region 14E is formed being in contact with the bottom portion of the N+ type emitter region 14E. For process rationalization, it is preferable that the N+ type emitter region 14E is formed by using the process of forming the N+ type source layer 14S and N+ type drain layer 14D of the NMOS transistor (the ion implantation of N type impurities). It is preferable that the N− type emitter region 12E is formed by using the process of forming the N− type source layer 12S and N− type drain layer 12D of the NMOS transistor (the ion implantation of N type impurities).

The N− type source layer 12S and N− type drain layer 12D of the NMOS transistor are formed deeper than the N+ type source layer 14S and N+ type drain layer 14D, and for that end, for example, the N+ type source layer 14S and the N+ type drain layer 14D are formed by ion implantation of arsenic and the N− type source layer 12S and the N− type drain layer 12D are formed by ion implantation of phosphorus. When the NMOS transistor is a high breakdown voltage transistor, the N− type source layer 12S and the N− type drain layer 12D are deepened by thermal diffusion first, and the N+ type source layer 14S and the N+ type drain layer 14D are then formed. By this, the N− type emitter region 12 is also formed deep like the N− type source layer 12S and the N− type drain layer 12D.

The N+ type emitter region 14E forms the same impurity concentration structure as the LDD structure of the NMOS transistor vertically. In detail, the N+ type emitter region 14E is formed with the N− type emitter region 12E extending in the vertical direction (in the depth direction) in contact with the bottom portion of the N+ type emitter region 14E and having a concentration lower than the N+ type emitter region 14E.

By this, the base width under the N+ type emitter region 14E is the vertical width of the P type base region 7 between the N− type emitter region 12E and the N type base width control layer 9, and smaller than in the first embodiment by the width of the N− type emitter region 12E.

The V-NPN transistor of the second embodiment obtains larger hFE (e.g. 170 or more) than the V-NPN transistor of the first embodiment which does not have the N− type emitter region 12E. The N− type emitter region 12E may be also formed being in contact with the side surface of the N+ type emitter region 14E and extending in the transverse direction as well as being in contact with the bottom portion of the N+ type emitter region 14E by extending the ion implantation region of the N− type emitter region 12E in the transverse direction by adjusting the photomask in the photolithography process before the ion implantation. This further increases the hFE.

### Third Embodiment

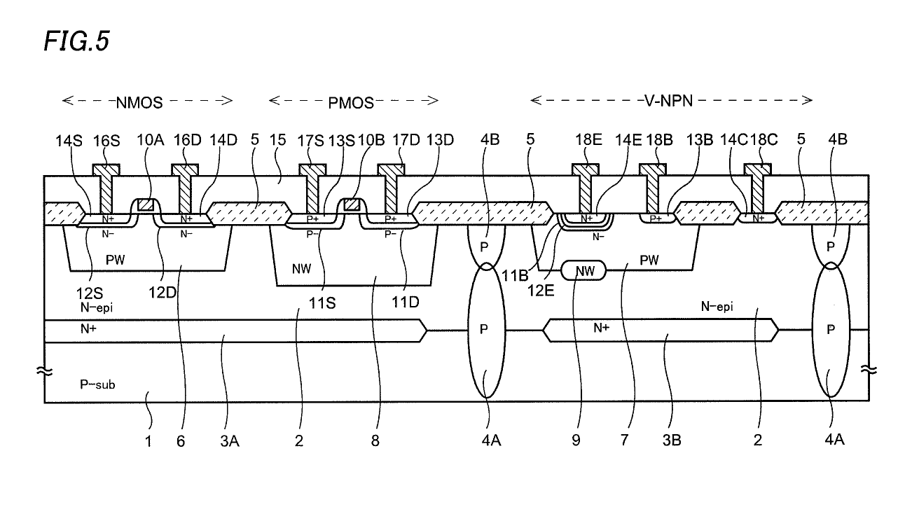

FIG. 5 is a cross-sectional view of a semiconductor device of a third embodiment of the invention. The third embodiment differs from the second embodiment (FIG. 4) in that a P+ type base region 11E having a concentration higher than the P type base region 7 is formed being in contact with the bottom portion of the N− type emitter region 12E. For process rationalization, it is preferable that the P+ type base region 11E is formed by using the process of forming the deep P− type source layer 11S and P− type drain layer 11D of the PMOS transistor (the ion implantation of P type impurities, e.g. boron).

In order to form the P− type source layer 115 and the P− type drain layer 11D deeper than the P+ type source layer 13S and the P+ type drain layer 13D, for example, the P− type source layer 11S and the P− type drain layer 11D are formed by ion implantation of boron and the P+ type source layer 13S and the P+ type drain layer 13D are formed by ion implantation of boron difluoride (BF₂). When the PMOS transistor is a high breakdown voltage transistor, the P− type source layer 11S and the P− type drain layer 11D are deepened by thermal diffusion first, and the P+ type source layer 13S and the P+ type drain layer 13D are then formed.

By the P+ type base region 11E, the concentration of the P type base region 7 becomes partially high under the N+ type emitter region 14E, and the N− type emitter region 12E becomes shallow by compensation. By this, the base width under the N+ type emitter region 14E becomes smaller than in the second embodiment, and thus the hFE of the V-NPN transistor of the third embodiment becomes a slightly smaller value than in the second embodiment.

In the third embodiment, too, the P+ type base region 11E may be formed being in contact with the side surface of the N− type emitter region 12E and extending in the transverse direction as well as being in contact with the bottom portion of the N− type emitter region 12E by extending the ion implantation region of the P+ type base region 11E in the transverse direction by adjusting the photomask in the photolithography process before the ion implantation.

### Fourth Embodiment

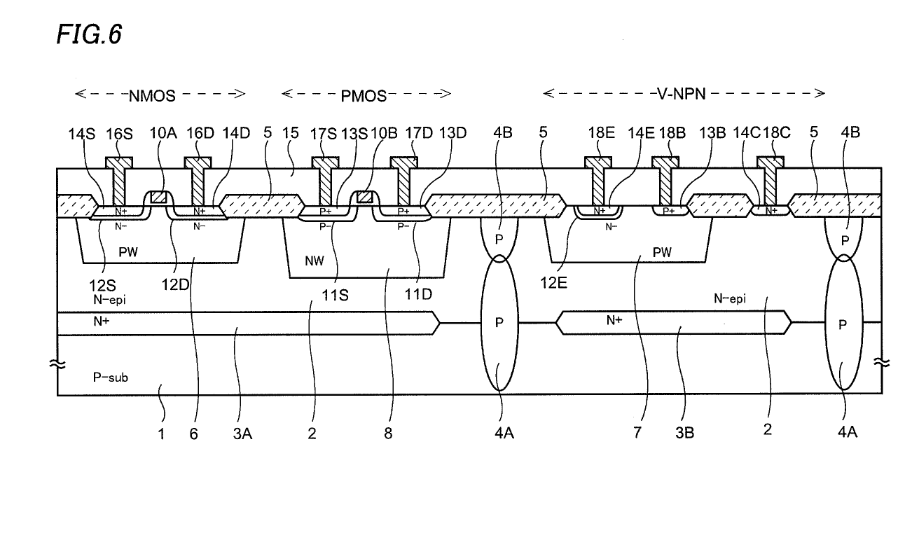

FIG. 6 is a cross-sectional view of a semiconductor device of a fourth embodiment of the invention. The fourth embodiment differs from the second embodiment (FIG. 4) in that the N type base width control layer 9 is removed. The N− type emitter region 12E having a concentration lower than the N+ type emitter region 14E is still formed being in contact with the bottom portion of the N+ type emitter region 14E.

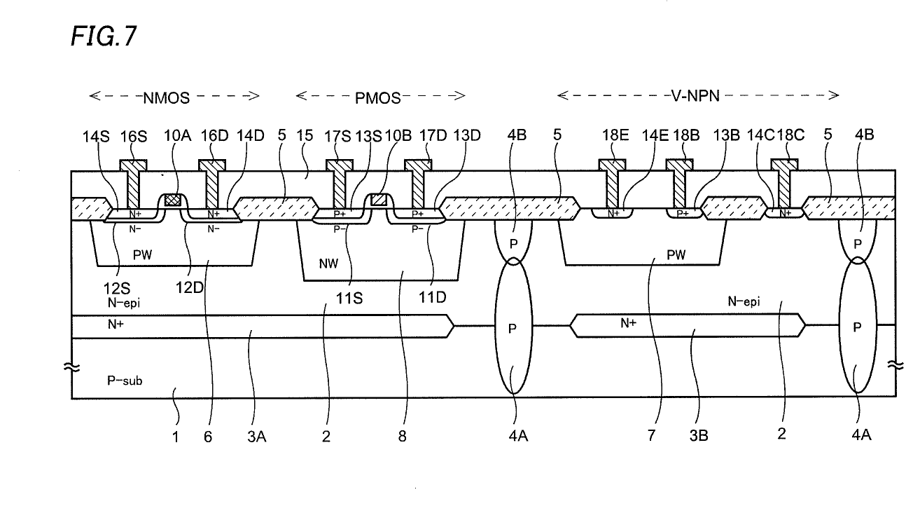

Therefore, in this case, the base width under the N+ type emitter region 14E is the vertical width of the P type base region 7 between the N− type emitter region 12E and the N− type epitaxial semiconductor layer 2 as the collector region. Although the hFE of the V-NPN transistor of the fourth embodiment becomes smaller than in the second embodiment, the hFE is still larger than a transistor which does not have the N− type emitter region 12E and the N type base width control layer 9 like a comparison example shown in FIG. 7.

The invention rationalizes a process of forming a V-NPN transistor of a semiconductor device which is manufactured by a BiCMOS process, and achieves a desired characteristic of the transistor, in particular, adjusts the hFE (direct current amplification factor) to a large value.

What is claimed is:

1. A semiconductor device comprising:
a semiconductor layer of a first general conductivity type;
a first MOS transistor of a first general conductivity channel type formed in the semiconductor layer;
a second MOS transistor of a second general conductivity channel type formed in the semiconductor layer;
a vertical bipolar transistor formed in the semiconductor layer; and
an isolation layer of the first general conductivity type electrically isolating the vertical bipolar transistor from the first and second MOS transistors,
wherein the vertical bipolar transistor comprises a base region of the second general conductivity type formed in a surface of the semiconductor layer, an emitter region of the first general conductivity type formed in a surface of the base region, and a base width control layer of the first general conductivity type extending from a bottom of the base region under the emitter region to upper area and lower area.

2. The semiconductor device of claim 1, wherein the vertical bipolar transistor comprises a low concentration emitter region of the first general conductivity type being in contact with a bottom portion of the emitter region.

3. The semiconductor device of claim 2, wherein the vertical bipolar transistor comprises a high concentration base region of the second general conductivity type being in contact with a bottom portion of the low concentration emitter region, and the second MOS transistor comprises a high concentration drain layer of the second general conductivity type and a low concentration drain layer of the second general conductivity type deeper than the high concentration drain layer of the second general conductivity type, the high concentration base region being formed by using a step of forming the low concentration drain layer of the second general conductivity type.

4. The semiconductor device of claim 3, wherein the vertical bipolar transistor comprises a base electrode drawing layer of the second general conductivity type formed in a surface of the base region, the base electrode drawing layer being formed by using a step of forming the high concentration drain layer of the second general conductivity type of the second MOS transistor.

5. The semiconductor device of claim 2, wherein the vertical bipolar transistor comprises a collector electrode drawing layer of the first general conductivity type in a surface of the semiconductor layer isolated by the isolation layer, and the first MOS transistor comprises a high concentration drain layer of the first general conductivity type and a low concentration drain layer of the first general conductivity type , the collector electrode drawing layer being formed by using a step of forming the high concentration drain layer of the first general conductivity type of the first MOS transistor.

6. The semiconductor device of claim 1, wherein the first MOS transistor comprises the first well region, the isolation layer is formed by using a step of forming the first well region.

7. A semiconductor device comprising:
a semiconductor layer of a first general conductivity type;
a first well region of a second general conductivity type formed in a surface portion of the semiconductor layer;
a first MOS transistor of a first general conductivity channel type formed in the first well region and comprising a high concentration drain layer of the first general conductivity type and a low concentration drain layer of the first general conductivity type deeper than the high concentration drain layer of the first general conductivity type; and
a second well region of the first general conductivity type formed in a surface portion of the semiconductor layer;
a second MOS transistor of a second general conductivity channel type formed in the second well region;
an isolation layer of the first general conductivity type formed in the semiconductor layer and electrically isolating a region of the semiconductor layer from the first and second well regions; and
a vertical bipolar transistor formed in the region of the semiconductor layer electrically isolated by the isolation layer,
wherein the vertical bipolar transistor comprises a base region of the second general conductivity type formed in a surface portion of the semiconductor layer electrically isolated by the isolation layer, an emitter region of the first general conductivity type formed in a surface portion of the base region, and a low concentration emitter region of the first general conductivity type being in contact with a bottom portion of the emitter region, the base region being formed by using a step of forming the first well region, the emitter region being formed by using a step of forming the high concentration drain layer of the first general conductivity type, and the low concentration emitter region being formed by using a process of forming the low concentration drain layer of the first general conductivity type.

8. A method of manufacturing a semiconductor device, comprising:
forming a first well region of a second general conductivity type in a surface portion of a semiconductor layer of a first general conductivity type;
forming a first MOS transistor of a first general conductivity channel type in the first well region;
forming a second well region of the first general conductivity type in a surface portion of the semiconductor layer;
forming a second MOS transistor of a second general conductivity channel type in the second well region;
forming a vertical bipolar transistor in the semiconductor layer; and
forming an isolation layer of the first general conductivity type electrically isolating a region of the semiconductor layer in which the vertical bipolar transistor is formed from the first and second MOS transistors,
the step of forming the vertical bipolar transistor, comprising:
forming a base region of the second general conductivity type in a surface portion of the semiconductor layer isolated by the isolation layer;
forming an emitter region of the first general conductivity type in a surface portion of the base region; and
forming a base width control layer of the first general conductivity type being in contact with a bottom portion of the base region under the emitter region so as to shallow the base region under the emitter region,
wherein the base region is formed by using the step of forming the first well region and the base width control layer is formed by using the step of forming the second well region.

9. The method of claim 8, wherein the step of forming the vertical bipolar transistor comprises forming a low concentration emitter region of the first general conductivity type being in contact with a bottom portion of the emitter region, the step of forming the first MOS transistor comprises forming a high concentration drain layer of the first general conductivity type and forming a low concentration drain layer of the first general conductivity type deeper than the high concentration drain layer of the first general conductivity type, the emitter region is formed by using the step of forming the high concentration drain layer of the first general conductivity type, and the low concentration emitter region is formed by using the step of forming the low concentration drain layer of the first general conductivity type.
